(19) United States
(12) Patent Application Publication
(10) Pub. No.: US 2014/0152293 A1
(43) Pub. Date: Jun. 5, 2014

(54) SENSING CIRCUIT

(71) Applicant: CORETEX TECHNOLOGY CORPORATION, New Taipei City (TW)

(72) Inventors: Chin-I HSIEH, New Taipei City (TW); Chien-Hsien TSAI, New Taipei City (TW)

(73) Assignee: CORETEX TECHNOLOGY CORPORATION, New Taipei City (TW)

(21) Appl. No.: 13/965,972

(22) Filed: Aug. 13, 2013

(30) Foreign Application Priority Data
Dec. 4, 2012 (TW) 101145387

(51) Int. Cl. G01R 23/00

(52) U.S. Cl. CPC G01R 23/005
USPC 324/76.44

(57) ABSTRACT

The present invention discloses a sensing circuit including a sensing device, a first amplifier circuit, a high-pass filter, a second amplifier circuit and a determination circuit. The sensing device produces a sensing signal. The first amplifier circuit reduces high-frequency components of the sensing signal and amplifies low-frequency components of the sensing signal to produce a first amplified signal. The high-pass filter removes the direct current of the first amplified signal to produce a filtered signal. The second amplifier amplifies low-frequency components of the filtered signal according to a first predetermined voltage to produce a second amplified signal. The determination circuit determines whether the second amplified signal is higher than a second predetermined voltage and lower than a third predetermined voltage, and produces a detection result when the second amplified signal is higher than the second predetermined voltage or lower than the third predetermined voltage.

### CROSS REFERENCE TO RELATED APPLICATIONS

This Application claims priority of Taiwan Patent Application No. 101145387, filed on Dec. 04, 2012, the entirety of which is incorporated by reference herein.

### BACKGROUND OF THE INVENTION

1. Field of the Invention

The present invention relates to a sensing circuit, and in particular relates to a sensing circuit without a large capacitor.

2. Description of the Related Art

Presently, electronic devices are highly developed and multi-functional, For example, handheld devices, such as mobile phones or tablets, have various sensing devices for executing applications in response to different environmental parameters.

Many of the sensing devices are arranged to detect the low-frequency signal between 0.4 Hz-7 Hz, such as a passive infrared sensor (PIR). However, the current filter circuits of passive infrared sensors are constituted by resistors with large resistance and capacitors with large capacitance to filter the received signal, wherein the resistors with large resistance and capacitors with large capacitance can make the filtered signal more accurate and avoid circuit malfunctions. However, the current filter circuits having resistors with large resistance and capacitors with large capacitance generally require 30 seconds to stabilize, as well as a large circuit layout area. Therefore, it is inconvenient for developers, and large capacitors can easily experience leakage problems. Therefore, the present invention provides a sensing circuit to solve these problems.

### BRIEF SUMMARY OF THE INVENTION

A detailed description is given in the following embodiments with reference to the accompanying drawings.

The present invention discloses a sensing circuit including a sensing device, a first amplifier circuit, a high-pass filter, a second amplifier circuit and a determination circuit. The sensing device is arranged to produce a sensing signal. The first amplifier circuit is arranged to reduce high-frequency components of the sensing signal and amplify low-frequency components of the sensing signal to produce a first amplified signal. The high-pass filter is arranged to remove the direct current of the first amplified signal to produce a filtered signal. The second amplifier circuit is arranged to amplify low-frequency components of the filtered signal according to a first predetermined voltage to produce a second amplified signal. The determination circuit is arranged to determine whether the second amplified signal is higher than a second predetermined voltage lower than a third predetermined voltage, and produce a detection result when the second amplified signal is higher than the second predetermined voltage or lower than the third predetermined voltage.

### BRIEF DESCRIPTION OF THE DRAWINGS

The present invention can be more fully understood by reading the subsequent detailed description and examples with references made to the accompanying drawings, wherein:

FIG. 1 is a schematic diagram illustrating an embodiment of a sensing circuit of the present invention;

FIG. 2 is a schematic diagram illustrating an embodiment of a first amplifier circuit of the present invention;

FIG. 3 is a schematic diagram illustrating an embodiment of a low-pass filter of the present invention;

FIG. 4 is a schematic diagram illustrating an embodiment of a high-pass filter of the present invention;

FIG. 5 is a schematic diagram illustrating an embodiment of a second amplifier circuit of the present invention;

FIG. 6 is a schematic diagram illustrating an embodiment of a determination circuit of the present invention;

FIG. 7 is a schematic diagram illustrating an embodiment of a voltage generator of the present invention;

FIG. 8 is a schematic diagram illustrating an embodiment of a sensing circuit of the present invention;

FIG. 9 is a signal simulation of a sensing circuit according to the embodiments of the present invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

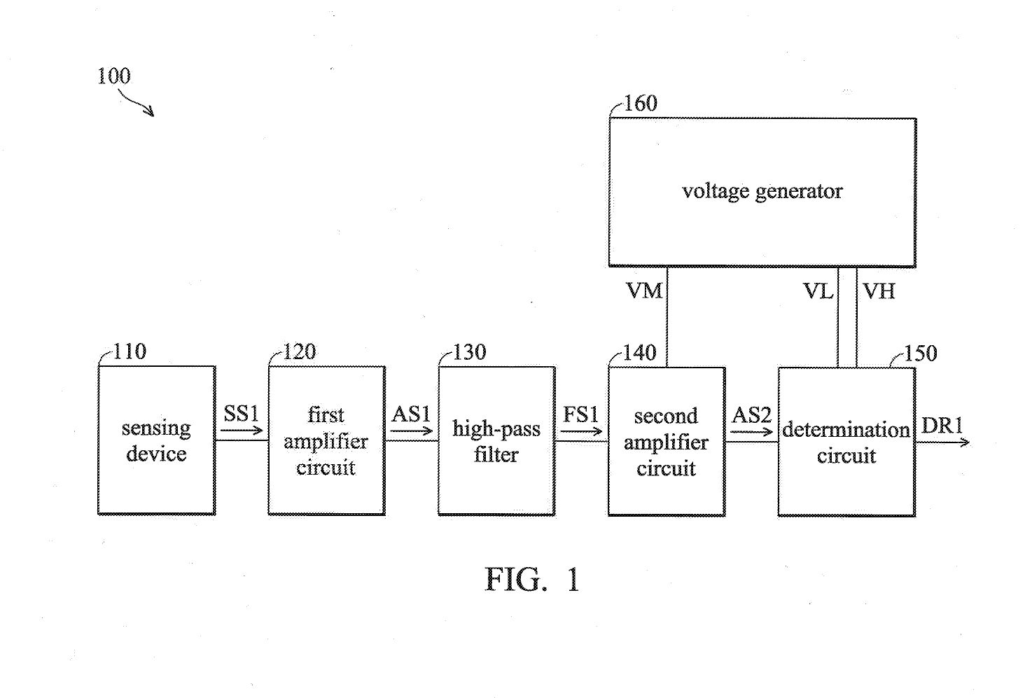

FIG. 1 is a schematic diagram illustrating an embodiment of a sensing circuit of the present invention. The sensing circuit 100 includes a sensing device 110, a first amplifier circuit 120, a high-pass filter 130, a second amplifier circuit 140, a determination circuit 150 and a voltage generator 160. The sensing circuit 200 can be applied in a computer configuration, such as a hand-held device, a multi-processor system, microprocessor-based, programmable consumer electronics, video surveillance equipment and household appliances, but it is not limited thereto.

The sensing device 110 is arranged to detect the surrounding environment and produce a sensing signal SS1. Moreover, the sensing device 110 is further arranged to transmit the sensing signal SS1 to the first amplifier circuit 120. In the present invention, the sensing device 110 is arranged to detect a low-frequency signal in the surrounding environment. One of the embodiments, the sensing device 110 is a passive infrared sensor (PIR) arranged to detect low-frequency signals, such as signals at about 1 Hz. Therefore, the filters of the present invention are arranged to pass frequencies within a certain range between 0.4 Hz˜7 Hz. In other embodiments, the sensing device 110 can also be other sensing devices arranged to detect low-frequency signals, but it is not limited thereto.

The first amplifier circuit 120 is coupled between the sensing device 110 and the high-pass filter 130. The first amplifier circuit 120 is arranged to receive the sensing signal SS1 produced by the sensing device 110. Moreover, the first amplifier circuit 120 is further arranged to reduce the high-frequency components of the sensing signal SS1 and amplify the low-frequency components of the sensing signal SS1 to produce a first amplified signal AS1. Next, the first amplifier circuit 120 provides the first amplified signal AS1 to the high-pass filter 130.

The high-pass filter 130 is coupled between the first amplifier circuit 120 and the second amplifier circuit 140. The high-pass filter 130 is arranged to receive the first amplified signal AS1 produced by the first amplifier circuit 120. The high-pass filter 130 is further arranged to remove the direct current of the first amplified signal AS1 to produce a filtered signal FS1, and provide the filtered signal FS1 to the second amplifier circuit 140.

The second amplifier circuit 140 is coupled to the high-pass filter 130, the voltage generator 160 and the determination circuit 150. The second amplifier circuit 140 is arranged to a amplify the low-frequency components of the filtered signal FS1 according to a first predetermined voltage VM produced by the voltage generator 160 to produce a second amplified signal AS2. The second amplifier circuit 140 is further arranged to provide the second amplified signal AS2 to the determination circuit 150.

The determination circuit 150 is coupled between the second amplifier circuit 140 and the voltage generator 160. The determination circuit 150 is arranged to determine whether the second amplified signal AS2 is higher than a second predetermined voltage VH and whether the second amplified signal AS2 is lower than a third predetermined voltage VL. The determination circuit 150 is further arranged to produce a detection result DR1 when the second amplified signal AS2 is higher than the second predetermined voltage VH or lower than the third predetermined voltage VL.

The voltage generator 160 is coupled between the second amplifier circuit 140 and the determination circuit 150. The voltage generator 160 is arranged to produce the first predetermined voltage VM, the second predetermined voltage VH and the third predetermined voltage VL, wherein the voltage generator 160 is further arranged to provide the first predetermined voltage VM to the second amplifier circuit 140 and provide the second predetermined voltage VH and the third predetermined voltage VL to the determination circuit 150. It should be noted that the first predetermined voltage VM is the average of the second predetermined voltage VH and the third predetermined Voltage VL, but it is not limited thereto.

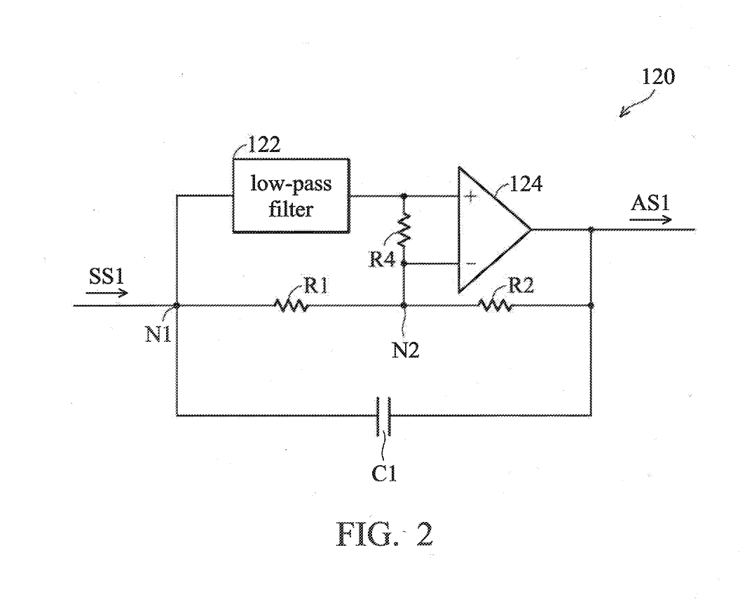

FIG. 2 is a schematic diagram illustrating an embodiment of a first amplifier circuit of the present invention. In this embodiment, the first amplifier circuit 120 includes a low-pass filter 122, a first resistor R1, a first amplifier circuit 124, a second resistor R2, a first capacitor C1 and a fourth resistor R4. The low-pass filter 122 has a first terminal coupled to a first node N1 and a second terminal coupled to the positive input terminal of the first amplifier circuit 12, wherein the low-pass filter 122 is arranged to reduce the high-frequency components of the sensing signal SS1. The first resistor R1 has a first terminal coupled to the first node N1 and a second terminal coupled to a second node N2. The second resistor R2 has a first terminal coupled to the second node N2 and a second terminal coupled to the output terminal of the first amplifier circuit 124. The first amplifier circuit 124 has a positive input terminal coupled to the second terminal of the low-pass filter 122, a negative input terminal coupled to the second node N2 and an output terminal arranged to produce the first amplified signal AS1, wherein the first amplifier circuit 124 is arranged to amplify the low-frequency components of the sensing signal SS1 according to the resistance ratio of the first resistor R1 and the second resistor R2. In one of the embodiments of the present invention, the resistance of the second resistor R2 is 100 times higher than the resistance of the first resistor R1. For example, the resistance of the first resistor R1 is 10 KΩ, and the resistance of the second resistor 1.2 is 1000 KΩ, but they are not limited thereto. It should be noted that, in this embodiment, the first amplifier circuit 124 is arranged to amplify the low-frequency components Of the sensing signal SS1 100 times according to the resistance ratio of the first resistor R1 and the second resistor R2. The first capacitor C1 has a first terminal coupled to the first node N1 and a second terminal coupled to the output terminal of the first amplifier circuit 124. The first capacitor C1 is arranged to pass the high-frequency components of the sensing signal SS1, such that the high-frequency components of the sensing signal SS1 are not amplified by the first amplifier circuit 124. In one of the embodiments of the present invention, the capacitance of the first capacitor C1 is 0.1 μF, but it is not limited thereto. In other embodiments, the first capacitor C1 can be other capacitors with small capacitance arranged to pass high-frequency components. The fourth resistor R4 is coupled between the positive input terminal and the negative input terminal of the first amplifier circuit 124.

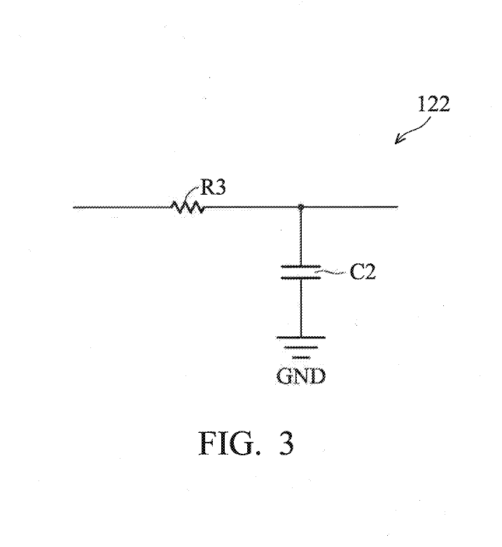

FIG. 3 is a schematic diagram illustrating an embodiment of a low-pass filter of the present invention, In this embodiment, the low-pass filter 122 includes a third resistor R3 and a second capacitor C2, but it is not limited thereto. The third resistor R3 has a first terminal coupled to the first node N1 and a second terminal coupled to the positive input terminal of the first amplifier circuit 124. The second capacitor C2 has a first terminal coupled to the second terminal of the third resistor R3, and a second terminal coupled to a ground GND. In one of the embodiments of the present invention, the resistance of the third resistor R3 is 200 KΩ, and the capacitance of the second capacitor C2 is 2.2 μF, but it is not limited thereto.

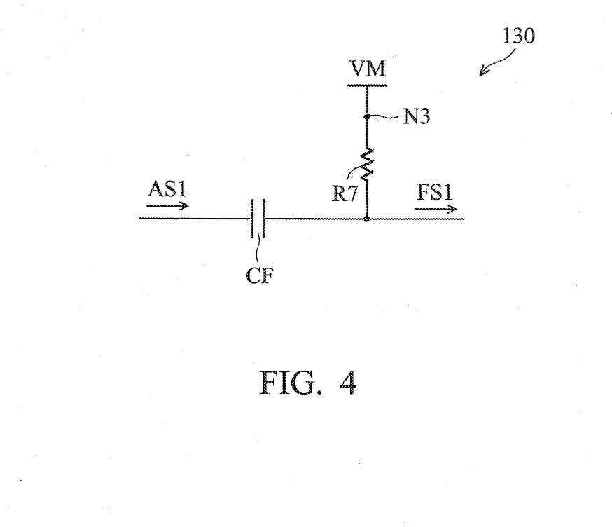

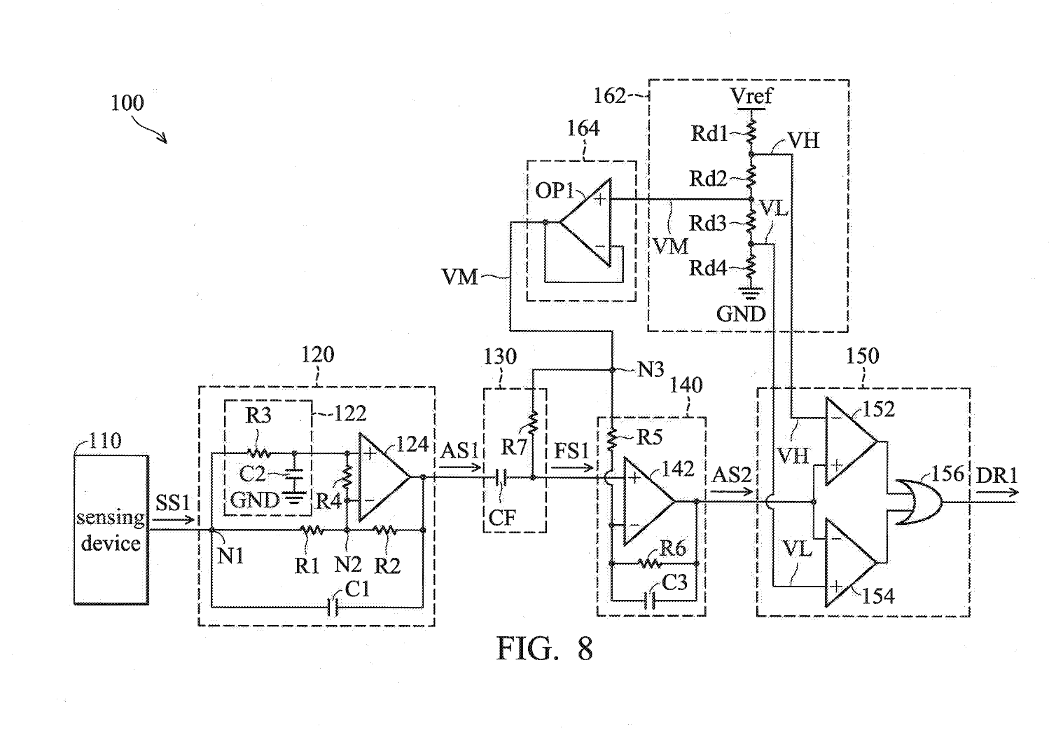

FIG. 4 is a schematic diagram illustrating an embodiment of a high-pass filter of the present invention. In this embodiment, the high-pass filter 130 includes a seventh resistor R7 and a filter capacitor CF. The filter capacitor CF has a first terminal coupled to the first amplifier circuit 120 and a second terminal coupled to the second terminal of the seventh resistor R7 and the second amplifier circuit 140, wherein the filter capacitor CF is arranged to remove the direct current of the first amplified signal AS1 to produce a filtered signal FS1, and provide, the filtered signal PS1 to the second amplifier circuit 140. For example, the capacitance of the filter capacitor CF is 1 μF. The seventh resistor R7 has a first terminal coupled to a third node N3 and a second terminal coupled to the second amplifier circuit 140, wherein the first terminal of the seventh resistor R7 is arranged to receive the first predetermined voltage VM and the seventh resistor R7 is arranged to pull high the filtered signal FS1 by the first predetermined voltage VM produced by the voltage generator 160. It should be noted that the second terminal of the seventh resistor R7 is coupled to the positive input terminal of the second amplifier circuit 142 of the second amplifier circuit 140, as shown in FIG. 8. In one of the embodiments of the present invention, the seventh resistor R7 is 400 KΩ, but it is not limited thereto.

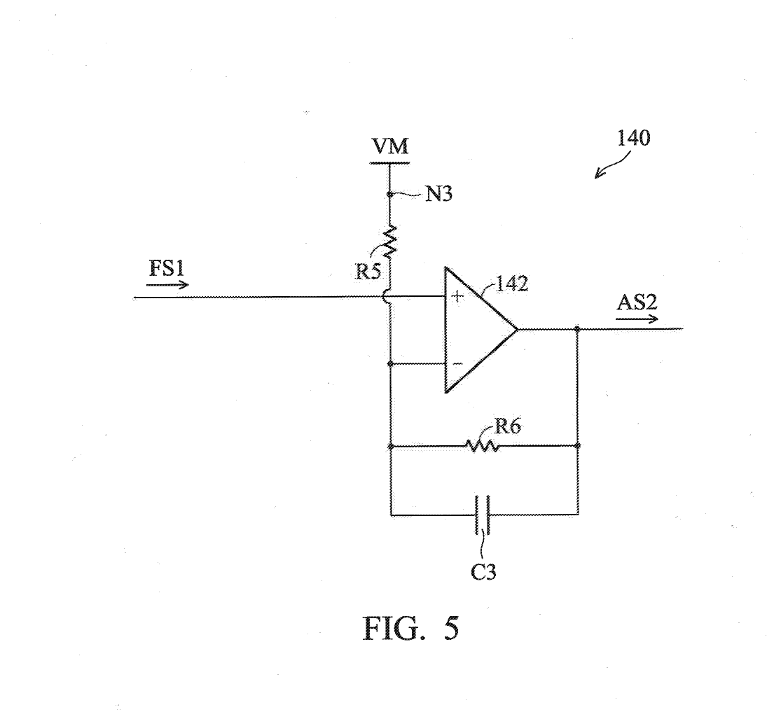

FIG. 5 is a schematic diagram illustrating an embodiment of a second amplifier circuit of the present invention. In this embodiment, the second amplifier circuit 140 includes a fifth resistor R5, a second amplifier circuit 142, a sixth resistor R6 and a third capacitor C3. The fifth resistor R5 has a first terminal coupled to a third node N3 and a second terminal coupled to the negative input terminal of the second amplifier circuit 142, wherein the first terminal of the fifth resistor R5 is arranged to receive the first predetermined voltage VM produced by the voltage generator 160. The sixth resistor R6 has a first terminal coupled to the negative input terminal of the second amplifier circuit 142, and a second terminal coupled to the output terminal of the second amplifier circuit 142. The second amplifier circuit 142 has a positive input terminal coupled to the high-pass filter 130 for receiving the filtered signal FS1, a negative input terminal coupled to the second terminal of the fifth resistor R5, and an output terminal arranged to produce the second amplified signal AS2, wherein the second amplifier circuit 142 is arranged to amplify the low-frequency components of the filtered signal FS1 according to the resistance ratio of the fifth resistor R5 and the sixth resistor R6. In one of the embodiments of the present invention, the resistance of the fifth resistor R5 is 25 times larger than the resistance of the sixth resistor R6. For example, the resistance of the fifth resistor R5 is 20 KΩ, and the resistance of the sixth resistor R6 is 500 KΩ, but they are not limited thereto. It should be noted that, in this embodiment, the second amplifier circuit 142 is arranged to amplify the low-frequency components of the filtered signal FS1 25 times. The third capacitor C3 has a first terminal coupled to the negative input terminal of the second amplifier circuit 142 and a second terminal coupled to the output terminal of the second amplifier circuit 142, wherein the third capacitor C3 is arranged to pass the high-frequency components of the filtered signal FS1, such that the high-frequency components of the filtered signal FS1 are not amplified by the second amplifier circuit 142. In one of the embodiments of the present invention, the capacitance of the third capacitor C3 is 0.022 μf, but it is not limited thereto. In other embodiments, the third capacitor C3 can also be other capacitors with small capacitance arranged to pass high-frequency components.

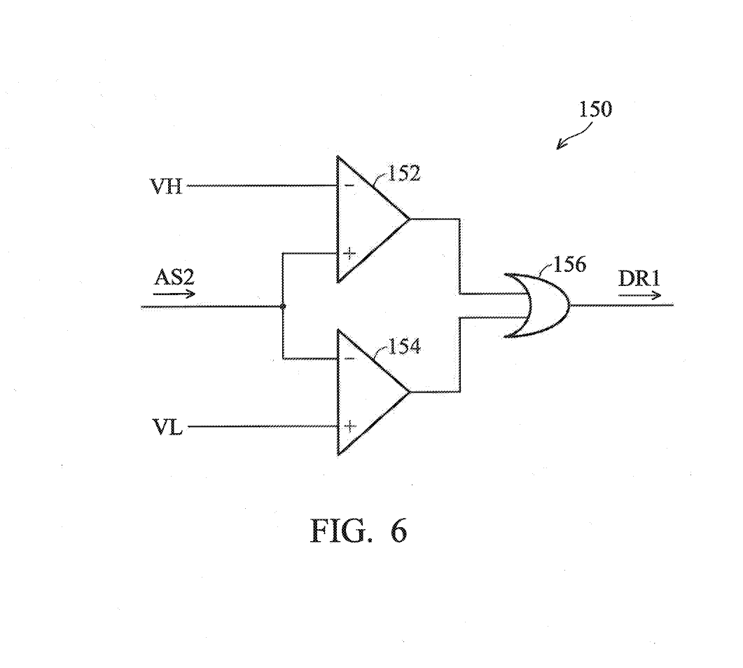

FIG. 6 is a schematic diagram illustrating an embodiment of a determination circuit of the present invention. In this embodiment, the determination circuit 150 includes a first comparator 152, a second comparator 154 and an OR gate 156, but it is not limited thereto. The first comparator 152 has a positive input terminal arranged to receive the second amplified signal AS2, a negative input terminal arranged to receive the second predetermined voltage VH produced by the voltage generator 160, and an output terminal coupled to the OR gate 156, wherein the first comparator 152 is arranged to determine whether the second amplified signal AS2 is higher than the second predetermined voltage VH. The second comparator 154 has a positive input terminal arranged to receive the third predetermined voltage VL produced by the voltage generator 160, and a negative input terminal arranged to receive the second amplified signal AS2, and an output terminal coupled to the OR gate 156, wherein the second comparator 154 is arranged to determine whether the second amplified signal AS2 is lower than the third predetermined voltage VL. The OR gate 156 has a first input terminal coupled to the output terminal of the first comparator 152, a second input terminal coupled to the output terminal of the second comparator 154, and an output terminal arranged to produce the detection result DR1 when the second amplified signal AS2 is higher than the second predetermined voltage VH or lower than the third predetermined voltage VL.

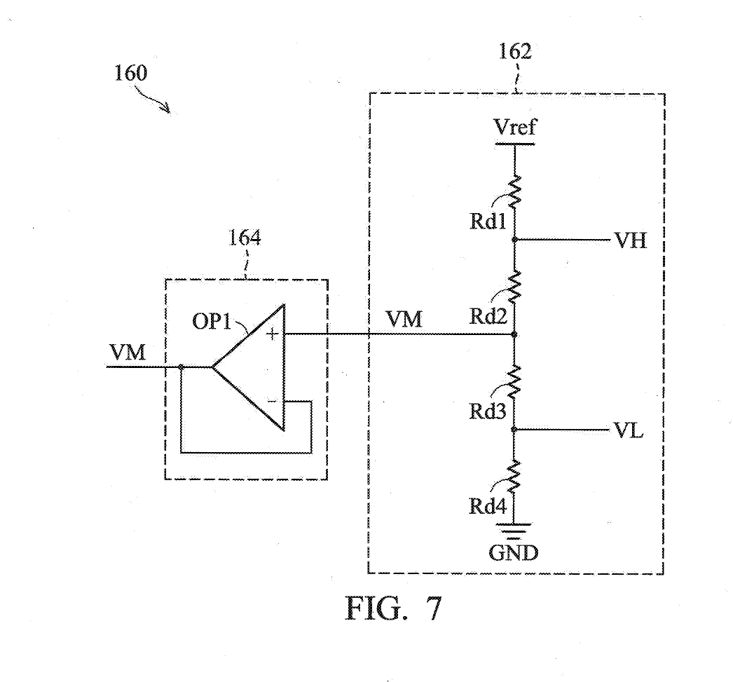

FIG. 7 is a schematic diagram illustrating an embodiment of a voltage generator of the present invention. In this embodiment, the voltage generator 160 includes a divider circuit 162 and a unity-gain buffer 164. The divider circuit 162 includes a first divider resistor Rd1, a second divider resistor Rd2, a third divider resistor Rd3, and a fourth divider resistor Rd4, but it is not limited thereto. The first divider resistor Rd1 has a first terminal coupled to a reference voltage Vref and a second terminal coupled to the first terminal of the second divider resistor Rd2, wherein the second terminal of the first divider resistor Rd1 is arranged to produce the second predetermined voltage VH. The second divider resistor Rd2 has a first terminal coupled to the second terminal of the first divider resistor Rd1, and a second terminal coupled to the first terminal of the third divider resistor Rd3, wherein the second terminal of the second divider resistor Rd2 is arranged to produce the first predetermined voltage VM. The third divider resistor Rd3 includes a first terminal coupled to the second terminal of the second divider resistor Rd2, and a second terminal coupled to the first terminal of the fourth divider resistor Rd4 to produce the third predetermined voltage VL. The fourth divider resistor Rd4 has a first terminal coupled to the second terminal of the third divider resistor Rd3, and a second terminal coupled to a ground GND. The unity-gain buffer 164 has an input terminal coupled to the second terminal of the second divider resistor Rd2, and an output terminal coupled to the second amplifier circuit 140, wherein the unity-gain buffer 164 is arranged to amplify the current of the first predetermined voltage VM, and provide the amplified first predetermined voltage VM to the second amplifier circuit 140. In one of the embodiments of the present invention, the unity-gain buffer 164 is an amplifier OP1 wherein the amplifier OP1 has a positive input terminal coupled to the second terminal of the second divide resistor Rd2, a negative input terminal, and an output terminal coupled to the second amplifier circuit 140 and the negative input terminal of itself, but it is not limited thereto.

FIG. 8 is a schematic diagram illustrating an embodiment of a sensing circuit of the present invention. The sensing circuit 100 of FIG. 8 includes the first amplifier circuit 120, the high-pass filter 130, the second amplifier circuit 140, the determination circuit 150 and a voltage generator 160 of FIG. 2-7. In this embodiment, the capacitances of the capacitors of the sensing circuit 100 are less than 5 μF. In another embodiment, the capacitances of the capacitors of the sensing circuit 100 are less than 3 μF. Therefore, the sensing circuit 100 disclosed by the present invention has a smaller area and better stability than the sensing circuit of the prior art. Moreover, the sensing circuit 100 provided by the present invention does not have large capacitor, such that the sensing circuit 100 can stabilize in a short e to detect the signal. Therefore, the sensing circuit 100 of the present invention can reduce the testing period. Furthermore, the fourth resistor R4 is further arranged to reduce the charging period of the second capacitor C2.

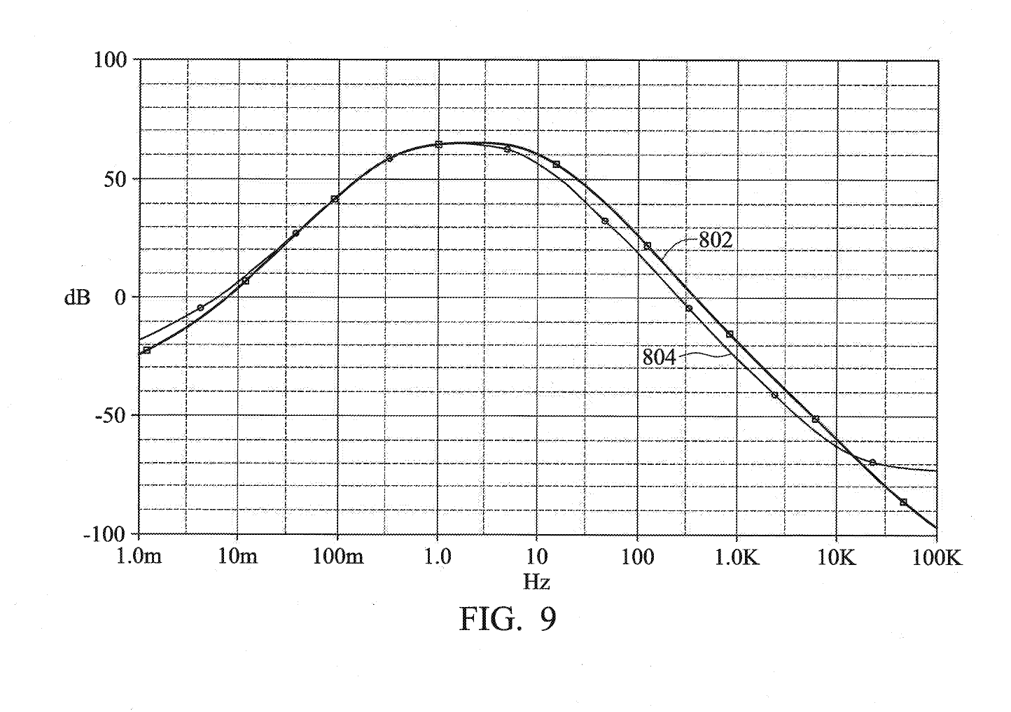

FIG. 9 is a signal simulation of a sensing circuit according to the embodiments of the present invention. FIG. 9 includes the frequency response 804 of a prior sensing circuit and the frequency response 802 of the sensing circuit 100 disclosed by the present invention. As per the frequency response 804 and the frequency response 802 shown in FIG. 9, the sensing circuit 100 has better suppression on the low frequency (0.01 Hz) and the high frequency (up to 10 kHz) than the sensing circuit of the prior art.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A sensing circuit, comprising:
a sensing device, arranged to produce a sensing signal;
a first amplifier circuit, arranged to reduce high-frequency components of the sensing signal and amplify low-frequency components of the sensing signal to produce a first amplified signal;
a high-pass filter, arranged to remove the direct current of the first amplified signal to produce a filtered signal;
a second amplifier circuit, arranged to amplify low-frequency components of the filtered signal according to a first predetermined voltage to produce a second amplified signal; and
a determination circuit, arranged to determine whether the second amplified signal is higher than a second predetermined voltage and lower than a third predetermined voltage, and produce a detection result when the second amplified signal is higher than the second predetermined voltage or lower than the third predetermined voltage.

2. The sensing circuit as claimed in claim 1, wherein the first amplifier circuit further comprises:
a low-pass filter, having a first terminal coupled to a first node, and a second terminal;
a first resistor, having a first terminal coupled to the first node, and a second terminal coupled to a second node;
a first amplifier circuit, having a positive input terminal coupled to the second terminal of the low-pass filter, a negative input terminal coupled to the second node, and an output terminal arranged to produce the first amplified signal;
a second resistor, having a first terminal coupled to the second node, and a second terminal coupled to the output terminal of the first amplifier circuit; and
a first capacitor, having a first terminal coupled to the first node, and a second terminal coupled to the output terminal of the first amplifier circuit.

3. The sensing circuit as claimed in claim 2, wherein the low-pass filter further comprises:
a third resistor, having a first terminal coupled to the first node, and a second terminal coupled to the positive input terminal of the first amplifier circuit; and
a second capacitor, having a first terminal coupled to the second terminal of the third resistor, and a second terminal coupled to a ground.

4. The sensing circuit as claimed in claim 2, wherein the first amplifier circuit further comprises a fourth resistor coupled between the positive input terminal and the negative input terminal of the first amplifier circuit.

5. The sensing circuit as claimed in claim 1, wherein the second amplifier circuit further comprises:
a fifth resistor, having a first terminal coupled to a third node arranged to receive the first predetermined voltage, and a second terminal;
a second amplifier circuit, having a positive input terminal coupled to the high-pass filter, a negative input terminal coupled to the second terminal of the fifth resistor, and an output terminal arranged to produce the second amplified signal, wherein the positive input terminal of the second amplifier circuit is arranged to receive the filtered signal;
a sixth resistor, having a first terminal coupled to the negative input terminal of the second amplifier circuit, and a second terminal coupled to the output terminal of the second amplifier circuit; and
a third capacitor, having a first terminal coupled to the negative input terminal of the second amplifier circuit, and a second terminal coupled to the output terminal of the second amplifier circuit.

6. The sensing circuit as claimed in claim 1, further comprising a voltage generator arranged to produce the first predetermined voltage, the second predetermined voltage, and the third predetermined voltage.

7. The sensing circuit as claimed in claim 6, wherein the voltage generator further comprises:
a divider circuit, comprising:
a first divider resistor, having a first terminal coupled to a reference voltage, and a second terminal arranged to produce the second predetermined voltage;
a second divider resistor, having a first terminal coupled to the second terminal of the first divider resistor, and a second terminal arranged to produce the first predetermined voltage;
a third divider resistor, having a first terminal coupled to the second terminal of the second divider resistor, and a second terminal arranged to produce the third predetermined voltage; and
a fourth divider resistor, having a first terminal coupled to the second terminal of the third divider resistor, and a second terminal coupled to a ground; and
a unity-gain buffer, having an input terminal coupled to the second terminal of the second divider resistor, and an output terminal coupled to the second amplifier circuit.

8. The sensing circuit as claimed in claim 1, wherein the determination circuit further comprises:
a first comparator, having a positive input terminal arranged to receive the second amplified signal, a negative input terminal arranged to receive the second predetermined voltage, and an output terminal;
a second comparator, having a positive input terminal arranged to receive the third predetermined voltage, a negative input terminal arranged to receive the second amplified signal, and an output terminal; and
an OR gate, having a first input terminal coupled to the output terminal of the first comparator, a second input terminal coupled to the output terminal of the second comparator, and an output terminal arranged to produce the detection result.

9. The sensing circuit as claimed in claim 1, wherein the high-pass filter further comprises:
a seventh resistor, having a first terminal coupled to a third node arranged to receive the first predetermined voltage, and a second terminal coupled to the second amplifier circuit; and
a filter capacitor, having a first terminal coupled to the first amplifier circuit, and a second terminal coupled to the second terminal of the seventh resistor.

10. The sensing circuit as claimed in claim 1, wherein the first predetermined voltage is the average of the second predetermined voltage and the third predetermined voltage.
